(19) United States
(12) Patent Application Publication
(10) Pub. No.: US 2003/0149924 A1
(43) Pub. Date: Aug. 7, 2003

(54) Method and apparatus for detecting faults on integrated circuits

(76) Inventors: Glenn E. Bedal, Chandler, AZ (US); David J. Urban, Ham Lake, MN (US); John Z. Nguyen, Maplewood, MN (US); Paul Huelskamp, St. Paul, MN (US)

Correspondence Address: INGRASSIA FISHER & LORENZ, P.C., 7150 E. CAMELBACK, STE. 325, SCOTTSDALE, AZ, 85251, US

(21) Appl. No.: 10/061,844

(22) Filed: Feb. 1, 2002

(51) Int. Cl. G01R 31/28

(52) U.S. Cl. 714/726

(57) ABSTRACT

A scan-cell for use in a scan device of the type which is utilized to test integrated circuits comprises a first multiplexer, a switching device, and a second multiplexer. The first multiplexer provides a data signal on the output thereof when a control signal is in a first state and provides a test signal at the output thereof when the control signal is in a second state. The switching device is coupled to the output of the first multiplexer and captures the output. The second multiplexer has an input coupled to the output of the switching device and transmits the output when the control signal is in the first state. The second multiplexer transmits an inverted form of the output when the control signal is in the second state.

### FIELD OF THE INVENTION

This invention relates generally to embedded structures for testing integrated circuits, and more particularly to a method and apparatus for performing on-board, in-circuit, scan-based testing of integrated circuits of the type used, for example, in implantable medical devices.

### BACKGROUND OF THE INVENTION

Historically, printed-circuit-board testing was accomplished using bed-of-nails in-circuit test equipment. However, the development of fine-pitch, high-count VLSI circuits (e.g. application specific integrated circuits) has encouraged the industry to develop test and fault detection protocols which do not require direct observability of locations within the circuitry as, for example, through the use test points and pins. The problem is further complicated by the advent of deep sub-micron technology (i.e. channel lengths no greater than about 0.5 microns) wherein faults are not only consistent with an open/short circuit fault model, but may also include faults characterized by a parasitic model; e.g. slow transitions and paths caused by, for example, particle random defects in the gate oxide, the inner-dielectric layers, or the interconnecting plugs and vias. These areas are especially vulnerable due to the geometry density and processing steps required to create them such as chemical/mechanical planarization.

While the problems are mitigated through the use of design-for-manufacturability techniques (i.e. metal/via density), faults and defects are not entirely eliminated. Even when using redundant via interconnects, one or more of the vias could be open or incomplete thus changing the resistivity through the interconnect. Furthermore, gate oxide defects can cause degradation in a transistor's turn-on/turn-off time thus impacting overall transition time which, in turn, could damage the device and create additional performance and/or reliability problems.

The above described defect mechanisms induce parametric variations, and the best method for detecting such variations is through time analysis and production time tests. The timing induced variations are most applicable to combinatorial logic and can be screened through timing thresholds by means of either frequency functional tests or delayed fault modeling. Unfortunately, partial testing at different frequencies is globally incomplete and does not detect all internal delay-induced defects. Alternatively, additional circuitry could be provided which permits individual clock-time control.

One known solution involves the use of scan-cells which provides virtual access around (i.e. a boundary scan-cell) or within (i.e. an internal scan-cell) circuitry by applying a stream of test vectors each comprised of serial patterns of ones and zeros to the integrated circuit device or portions thereof by means of, for example, one or more on-board shift registers deployed between blocks of combinatorial logic. The test pattern is shifted into the shift register and then into the logic circuitry to initialize the test paths of the logic circuitry, and the response data is captured to detect faults. During standard operations, the scan-cells remain inactive and allow data to propagate through the logic circuitry normally. However, during a test mode, the test pattern signals are preloaded into the shift register flip-flops, applied to the inputs of the logic elements for testing down-stream logic devices, and presented to the capture mechanism.

Obviously, to be effective, the time at which the scan pattern signals are applied to the logic inputs must be precisely determinable in order to accurately calculate the transition times and propagation delays of the individual logic elements and paths. For example, if two or more logical ones are shifted through adjacent bits of the shift register, a logical 1 may be applied to the input of the capture mechanism for more than one successive clock period. An increase in the path resistance manifested as increased delay might not be detected because the signal being captured by the capture mechanism may have commenced as a result of a previously shifted level.

One known solution to this problem involves the use of shadow flip-flops deployed between the shift register outputs and combinatorial logic. Shadow flip-flops mask the shift register loading process, and the signals stored in the shadow flip-flops are applied to the logic inputs at the same time during a subsequent time period. Obviously, this approach results in an increase in silicon overhead. Alternatively, the pattern capture may be performed using a double clock. That is, the pattern is captured during two successive clock periods. The first suffers from the above-described timing problems; however, a capture during the second clock period is done in parallel. While this method requires no adverse hardware impact, the resulting scan pattern is very complex and may still be unable to isolate all circuit paths.

In view of the foregoing, it should be appreciated that it would be desirable to provide a new scan-cell structure and method that provides for the implementation of fault testing on integrated circuits while maintaining circuit and silicon overhead to a minimum. Additional desirable features will become apparent to one skilled in the art from the foregoing background of the invention and following detailed description of a preferred exemplary embodiment and the appended claims.

### SUMMARY OF THE INVENTION

In accordance with the broad aspect of the invention there is provided a scan-cell for use in a device for testing integrated circuits. The scan-cell includes first and second multiplexers and a switching device. The first multiplexer provides a first signal to the switching device when the control signal is in a first state and a test signal to the switching device when the control signal is in a second state. The output of the switching device is coupled to the second multiplexer which transmits the output of the switching device when the control signal is in the first state and it transmits an inverted form thereof when the control signal is in the second state.

According to a further aspect of the invention there is provided a method for detecting faults in a logic circuit. A scan pattern is stored in a first plurality of input scan-cells. This scan pattern is then presented to the logic circuit when a control signal is in a first state. The scan pattern is inverted when the control signal transitions from its first state to its second state to create a measuring edge. The output of the logic circuit is then captured in a plurality of output scan-cells, and the delay between the measuring edge and the capture is measured to determine propagation delay.

### BRIEF DESCRIPTION OF THE DRAWINGS

The following drawings are illustrative of particular embodiments of the invention and therefore do not limit the scope of the invention, but are presented to assist in providing a proper understanding of the invention. The drawings are not to scale (unless so stated) and are intended for use in conjunction with the explanations in the following detailed description. The present invention will hereinafter be described in conjunction with the accompanying drawings, wherein like reference numerals denote like elements, and:

FIG. 1 is a functional block diagram illustrating the input and output structure of a simple scan-cell;

FIG. 2 is a functional block diagram of a scan device including a plurality of input scan cells, a plurality of output scan cells, bypass circuitry, an instruction register, a test access port, and a test access port controller;

FIG. 3 is a logic diagram illustrating a scan-cell in accordance with the prior art;

FIG. 4 is a logic diagram of a simplified scan device incorporating the scan-cell shown in FIG. 3; and

FIG. 5 is logic diagram illustrating a scan-cell in accordance with a first embodiment of the present invention.

### DESCRIPTION OF THE PREFFERED EXEMPLARY EMBODIMENTS

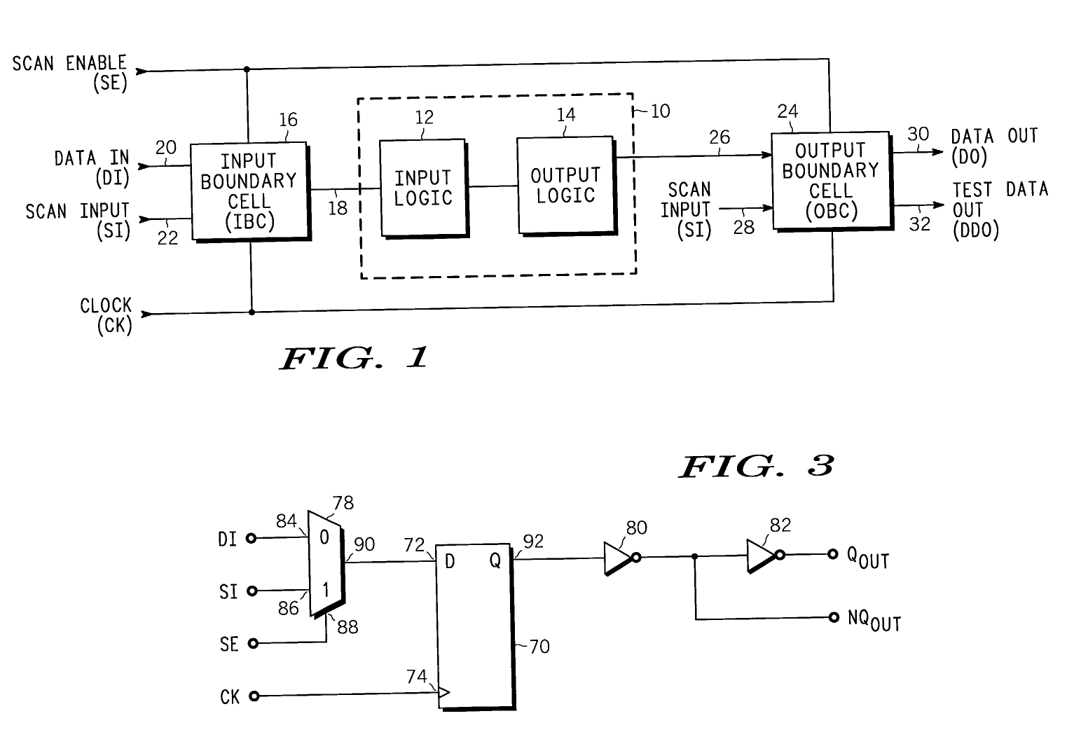

FIG. 1 is a simplified block diagram illustrating a basic scan device for providing onboard scan-based testing and fault detection for combinatorial logic circuits. Combinatorial logic circuit 10 is shown as generally comprising input logic circuitry 12 and output logic circuitry 14. An input boundary scan-cell (IBC) 16 is shown as having an output 18 which is applied to input logic 12. The data appearing at output 18 maybe legitimate data which is to be processed by logic circuit 10 or may be test data in the form of a scan pattern which is utilized to determine if logic circuit 10 is performing properly. Input boundary scan-cell 16 has a first input 20 for receiving legitimate data-in (DI) and a second input 22 which receives a scan input (SI) which consists of a stream of test vectors each comprised of serial patterns of ones and zeros.

An output boundary scan-cell (OBC) 24 has a first input 26 that is coupled to receive a signal from output logic circuit 14 and also includes a scan input 28 as did input boundary scan-cell 16. As can be seen, output boundary scan-cell 24 has a first output 30 corresponding to legitimate data-out (DO) and a second output 32 corresponding to test data-out (TDO). Both input boundary scan-cell 16 and output boundary scan-cell 24 have a third input for receiving a clock signal (CK) and a fourth input for receiving a scan enable signal (SE) which places both input boundary scan-cell 16 and output boundary scan-cell 24 a test mode. Thus, during normal operations, input boundary scan-cell 16 and output boundary scan-cell 24 permit data to be propagated through logic circuit 10 in the normal way. However, during test modes, test data (SI) is applied to logic circuit 10 via input boundary scan-cell 16, and the result of the test is captured in output boundary scan-cell 24 and made available at test data output (TDO) 32.

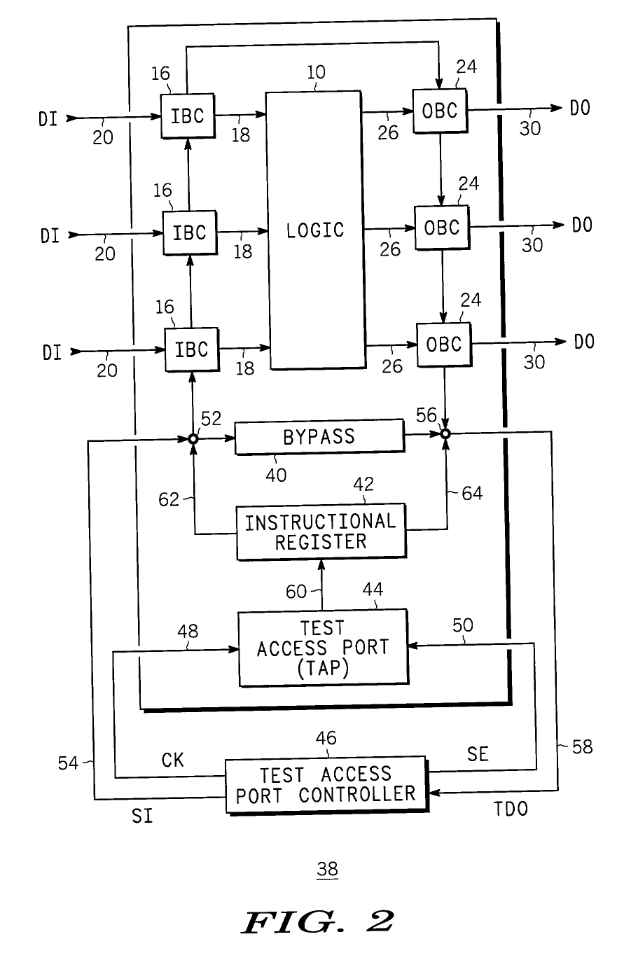

FIG. 2 is a functional block diagram that shows a scan device 38 comprising a plurality of input boundary scan-cells 16 having outputs 18 coupled to logic circuit 10 and a plurality of output boundary scan-cells 24 for receiving signals 26 from logic circuit 10. As previously described in connection with of FIG. 1, each input boundary scan-cell 16 has a data input 20 and an output signal 18. Similarly, each output boundary scan-cell 24 receives a signal 26 from logic circuit 10 and provides a data out signal 30.

The device shown in FIG. 2 further includes bypass circuit 40, instruction register 42, test access port (TAP) 44, and test access port controller 46. As can be seen, test access port controller 46 provides a clock signal (CK) to test access port 44 over line 48, a scan enable signal (SE) to test access port 44 over line 50, scan input data (SI) to combination nodes 52 over line 54, receives output test data (TDO) from combination node 56 over line 58, and performs the required measurements and calculations (e.g. propagation delay through logic 10). Instruction register 42 is coupled to test access port 44 as is shown at 60, and instruction register 42 provides inputs to combination nodes 52 and 56 over lines 62 and 64 respectively. Test access port 44, in conjunction with test access port controller 46, controls the basic operation of the device by generating the clock signal (CK), the scan enable signal (SE), the test data or scan input data (SI) and receiving the test data out (TDO).

Instruction register 42 generates instructions in response to signals received from test access port 44 which indicate how the device is to perform. For example, instruction register 42 may place the device into an external boundary test mode and select the boundary scan register to be connected between the SI output 54 and the TDO input 58. Boundary scan-cells 16 and 24 are then preloaded with test patterns in order to test logic circuitry 10. Input boundary scan-cells 16 capture the input test vectors for application to logic circuitry 10 when in the test mode.

The device's boundary scan chain can be bypassed through the use of bypass register 40. Bypass register 40 allows data to pass therethrough without incurring the additional overhead of traversing through other devices. Thus, the device can remain in a functional mode by selecting a bypass register to be coupled between the SI data applied to combination node 52 and the output test data originating at combination node 56. This allows serial data to be transferred through the device from combination nodes 52 to combination node 56 without impacting the operation of the overall device.

It should be clear that the block diagram shown in FIG. 2 has been simplified for the sake of understanding. For example, it should be clear that the clock signal (CK) and the scan enable signal (SE) are applied to each of the input boundary scan-cells and output boundary scan-cells as shown in FIG. 1. However, for the sake of convenience, they are shown as being applied only to test access port 44. Finally, it can be seen that scan data (SI) comprising a test vector which includes a pattern of ones and zeros is applied to combination node 52 over line 54 and is shifted through each of the input boundary scan-cells 16 and output boundary scan-cells 24 in order to precondition logic circuit 10.

The techniques described above in connection with the use of boundary scans as a methodology permitting complete controllability and observability of an integrated circuit's boundary pins under software control is well known. For example, see the white paper entitled “Introduction to JTAG Boundary Scan,” dated January 1997 provided by Sun MicroElectronics. For additional information, see U.S. Pat. No. 6,092,226 entitled “Fabrication of Test Logic for Level Sensitive Scan on a Circuit” issued Jul. 18, 2000 and U.S. Pat. No. 6,150,807 entitled “Integrated Circuit Architecture having Array of Test Cells Providing Full Controllability for Automatic Circuit Verification” issued Nov. 21, 2000.

FIG. 3 is a logic diagram of a typical scan-cell in accordance with the prior art. It includes a flip-flop 70 (e.g. a delay type flip-flop) having a D input 72, a clock input 74, a Q output 76, a multiplexer 78, and first and second inverters 80 and 82 respectively. Multiplexer 78 has a first input 84 coupled to receive normal data (DI), a second input 86 coupled to receive scan input data (SI), and an enable or gate input 88 coupled to receive a scan enable (SE) signal. Multiplexer 78 operates in the well-known manner. That is, when SE is high or at a logical 1, a test vector comprised of a serial string of ones and zeros (i.e. the scan input) is transmitted through multiplexer 78 to its output 90, which is in turn coupled to input 72 of storage flip-flop 70. When SE is low or a logical 0, normal data (DI) is transmitted through multiplexer 78 to input 72 of flip-flop 70. The signal appearing at the Q output 92 of flip-flop 70 passes through inverters 80 and 82 to produce a Qₒᵤₜ signal. An inverted output (NQₒᵤₜ) is taken from the output of inverter 80. Flip-flop 70 operates in the well-known manner. That is, upon the occurrence of a clock signal (CK) at input 74, the data at input 72 is switched into and stored in flip-flop 70 and appears at its Q output 92 for application to the input of inverter 80.

During normal mode, the scan enable (SE) signal is held low, and data (DI) is clocked into flip-flop 70 and appears at output Qₒᵤₜ and inverted output NQₒᵤₜ. During test mode, the scan enable (SE) signal is held high, and a scan pattern (SI) is shifted through flip-flop 70 (and subsequent flip-flops not shown). When all flip-flops in the scan chain have been updated, scan enable (SE) goes low. When the test has been completed, the data is shifted out of the chain.

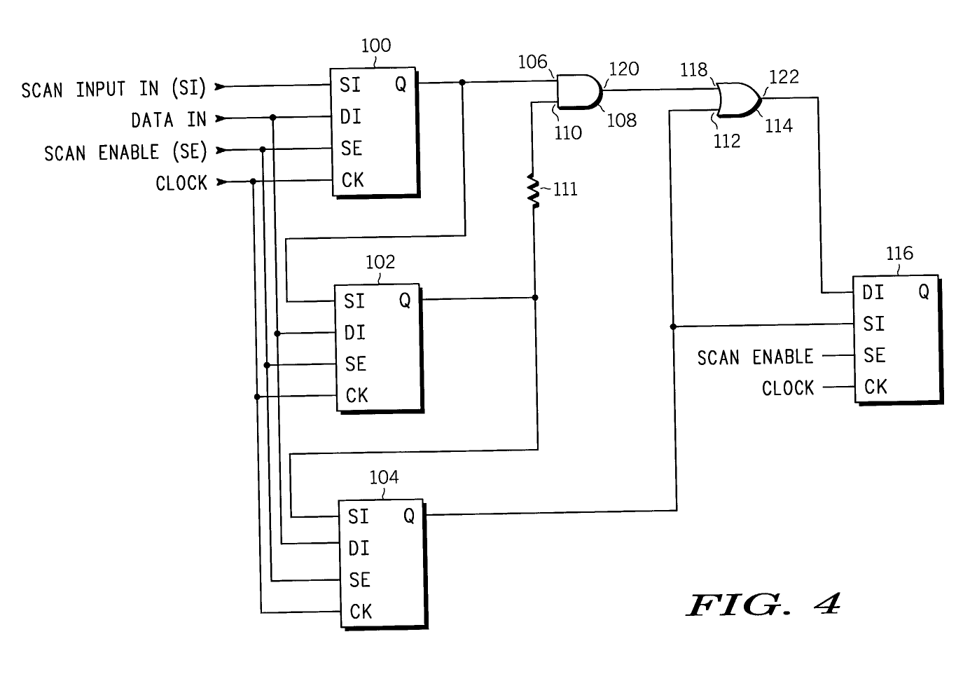

FIG. 4 is a simple logic diagram which illustrates the problem associated with using the scan-cell shown in FIG. 3. As can be seen, three scan-cells 100,102, and 104 are coupled in a shift register configuration. That is, the Q output of scan-cell 100 is applied to the scan input of scan-cell 102, and the Q output of scan-cell 102 is coupled to scan input of scan-cell 104. Each of scan-cells 100,102, and 104 also have inputs for receiving normal data (DI), a scan enable signal (SE), and a clock signal (CK) as previously described in connection with FIGS. 1, 2 and 3. The Q output of scan-cell 100 is coupled to a first input 106 of AND gate 108, the Q output of scan-cell 102 is coupled to a second input 110 of AND gate 108, and the Q output of scan-cell 104 is coupled to a first input 112 of OR gate 114 and to the SI input of capture scan-cell 160. OR gate 114 has a second input 118 coupled to output 120 of AND gate 108 and has an output 122 coupled to the DI input of capture scan-cell 116. Capture scan-cell 116 is also provided with inputs for receiving the clock signal (CK) and the scan enable signal (SE). In order to simplify the explanation of the problem, assume that the circuit has been preconditioned so as to detect only faults in the path between the Q output of scan-cell 102 and input 110 of AND gate 108 represented by resistance 111. That is, assume that input 106 of AND gate 108 is a logical 1. If we assume that the Q outputs of scan-cells 100, 102 and 104 are high, high, and low respectively, then a high or logical 1 at the Q output of scan-cell 116 would indicate that the path between the Q output of scan-cell 102 and input 110 of AND gate 108 is without fault. Now assume, however, that the potential fault being investigated is an increase in resistance in the path in question represented by resistor 111. This increase in resistance manifests itself as a delay element that might not be detected at the Q output of scan-cell 116.

The problem is easily appreciated in view of the fact that the above described scan devices were originally designed to detect “stuck-at-one” or “stuck-at-zero” types of faults and were not intended to detect resistive type faults (e.g. 10 Kohms) which would introduce an additional delay as short as, for example, 200 picoseconds. That is, the clock rate controlling (1) the shifting of the scan pattern into scan-cells 100, 102, and 104 and (2) the capture of the data (after SE goes low) at the output of OR gate 114 in scan-cell 116 is relatively slow.

The output of OR gate 114 can change with every scan pattern shift into scan-cells 100, 102, and 104. That is, a change in the Q output of the scan-cell 102 will impact the output of OR gate 114 very quickly even with the addition of a resistive delay 111. However, a much longer period of time (e.g. 30 nanoseconds) could elapse before this data is captured by scan-cell 116. Thus, the resistive fault will not be detected.

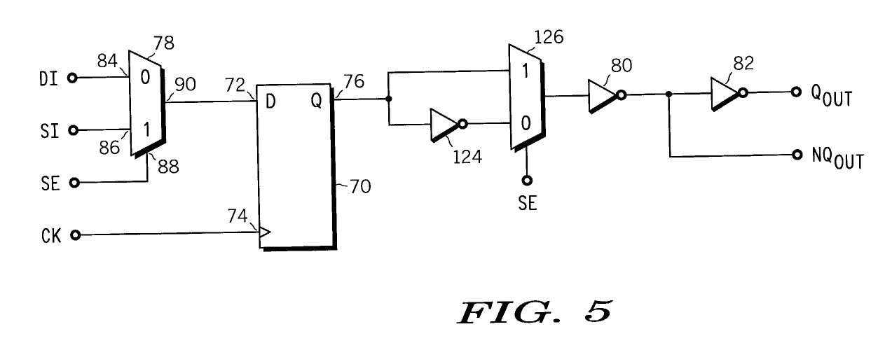

FIG. 5 is a logic diagram of a scan-cell in accordance with the present invention. As can be seen, it is identical to the scan-cell shown in FIG. 3 expect for the addition of inverter 124 and a second multiplexer 126. The Q output 76 of flip-flop 70 is coupled to a first output of multiplexer 126 and to the input of inverter 124. The output of inverter 124 is coupled to a second input of multiplexer 126, and the output of multiplexer 126 is coupled to the input of inverter 80. When scan enable (SE) is high, the Q output of flip-flop 70 is applied to the input of inverter 80 and appears at the output of inverter 82 (Qₒᵤₜ). When scan enable (SE) goes low, the output of inverter 124 is applied to the input of inverter 80.

Substituting the scan-cell shown in FIG. 5 for scan-cells 100, 102 and 104 shown in FIG. 4, when scan enable (SE) goes low, the outputs of scan-cells 100, 102 and 104 change state on the falling edge of scan enable, and the resultant output of the logic is presented at the DI input of scan-cell 116 almost immediately. This output is captured in scan-cell 116 on the leading edge of the next clock signal. Thus, not only are all the bits of the scan pattern contained in scan-cells 100, 102 and 104 and appearing at the Q outputs thereof applied to the logic to be tested at the same time, but it is a known, unambiguous time since it corresponds to the falling edge of scan enable (SE). Thus, an edge has been created from which the propagation delay through the logic can be unambiguously measured.

The following description is exemplary in nature and is not intended to limit the scope, applicability, or configuration of the invention in any way. Rather, the following description provides a convenient illustration for implementing exemplary embodiments of the invention. Various changes to the described embodiments may be made in the function and arrangement of the elements described herein without departing from the scope of the invention.

1. A scan-cell for use in a scan device of the type utilized to test integrated circuits, said scan-cell comprising:
a first multiplexer for providing a first signal on a first output thereof, said first signal corresponding to a first data signal when a control signal is a first state and said first signal corresponding to a test data signal when said control signal is in a second state;
a switching device having an input coupled to said first output for capturing said first signal and having a second output for providing a second signal; and
a second multiplexer having an input coupled to said second output for transmitting said second signal when said control signal is in said first state and for transmitting an inverted form of said second signal when said control signal is in said second state.

2. A scan-cell according to claim 1 wherein said switching device is a flip-flop.

3. A scan-cell according to claim 1 wherein said second multiplexer has a first input coupled to said second output and further comprising an inverter having an input coupled to said second output and having an output coupled to a second input of said second multiplexer.

4. A scan-cell according to claim 1 wherein said control signal is applied to said first and second multiplexers.

5. A scan device for detecting faults in a logic circuit, comprising:
a first plurality of input scan-cells for receiving a scan pattern and presenting said scan pattern to said logic circuit when a control signal is in a first state, each input scan-cell comprising:
a first multiplexer for providing a first signal at a first output thereof, said first signal corresponding to a first data signal when a control signal is in a first state and said first signal corresponding to a scan pattern signal when said control signal is in a second state;
a switching device having an input coupled to said first output for capturing said first signal and having a second output for providing a second signal; and
a second multiplexer having an input coupled to said second output for transmitting said second signal when said control signal is in said first state and for transmitting an inverted form of said second signal when said control signal is in said second state; and
a plurality of output scan-cells coupled to said logic circuit for capturing the results of said logic circuit operating on said scan pattern.

6. A scan device according to claim 5 wherein said switching device is a flip-flop.

7. A scan device according to claim 5 wherein said second multiplexer has a first input coupled to said second output and further comprising an inverter having an input coupled to said second output and having an output coupled to a second input of said second multiplexer.

8. A scan device according to claim 7 wherein said control signal is applied to said first and second multiplexers.

9. In a scan-cell of the type utilized to apply a test signal to at least one logic device when a control signal is in a first state, a method for measuring the propagation delay through said logic device, comprising:
presenting said test signal to said logic device when said control signal is in said first state; and
inverting said test signal when said control signal transitions from said first state to a second state to create a measuring edge.

10. A method according to claim 9 wherein the step of presenting comprises:
applying a first data signal to a first input of a first multiplexer;
applying said test signal to a second input of said first multiplexer; and
transmitting said test signal through said first multiplexer when said control signal is in said first state.

11. A method according to claim 10 wherein the step of presenting further comprises storing said test signal in an storage device having an input coupled to an output of said first multiplexer, said storage device having an output.

12. A method according to claim 11 wherein said step of inverting comprises:
applying the output of said storage device to a first input of a second multiplexer;
inverting the output of said storage device; and
applying the inverted output to a second input of said second multiplexer.

13. A method according to claim 12 wherein said control signal is applied to said first and second multiplexers to control the output thereof.

14. A method for detecting faults in a logic circuit comprising:
presenting a test signal to said logic circuit when a control signal is in the first state;
inverting said test signal when the control signal transitions from the first state to a second state to create a measuring edge;
capturing an output of said logic circuit in a second storage device, said output being responsive to the inverted test signal; and
measuring the time between said measuring edge and the capture of said output.

15. A method according to claim 14 wherein the step of presenting comprises:
applying a first data signal to a first input of a first multiplexer;
applying said test signal to a second input of said first multiplexer; and
transmitting said test signal through said first multiplexer when said control signal is in said first state.

16. A method according to claim 15 wherein the step of presenting further comprises storing said test signal in an storage device having an input coupled to an output of said first multiplexer, said storage device having an output.

17. A method according to claim 16 wherein the step of inverting comprises:
applying the output of said storage device to a first input of a second multiplexer;
inverting the output of said storage device; and
applying the inverted output to a second input of said second multiplexer.

18. A method according to claim 17 wherein said control signal is applied to said first and second multiplexers to control the output thereof.

19. A method for detecting faults in a logic circuit, comprising:
storing a scan pattern in a first plurality of input scan-cells;
presenting said scan pattern stored in said plurality of input scan-cells to said logic circuit when a control circuit is in a first state;
inverting said scan pattern presented to said logic circuit when said control circuit transitions from the first state to a second state to create a measuring edge;
capturing an output of said logic circuit in a second plurality of output scan-cells; and
measuring the delay between said measuring edge and the capture of the output of said logic circuit.

20. A method according to claim 19 wherein the step of inverting comprises:
applying the output of said storage device to a first input of a second multiplexer;
inverting the output of said storage device; and
applying the inverted output to a second input of said second multiplexer.
